(19) United States
(12) Patent Application Publication
(10) Pub. No.: US 2025/0133909 A1
(43) Pub. Date: Apr. 24, 2025

(54) DISPLAY DEVICE AND METHOD FOR FABRICATING THE SAME

(71) Applicant: Samsung Display Co., LTD., Yongin-si (KR)

(72) Inventors: Hyun Eok SHIN, Yongin-si (KR); Jong Hee PARK, Yongin-si (KR); Yun Jong YEO, Yongin-si (KR); Sung Soon IM, Yongin-si (KR)

(21) Appl. No.: 18/655,098

(22) Filed: May 3, 2024

(30) Foreign Application Priority Data
Oct. 24, 2023 (KR) 10-2023-0142570

(51) Int. Cl. H10K 59/122; G09G 3/3233; H10K 71/20

(52) U.S. Cl. CPC H10K 59/122; H10K 71/233; G09G 3/3233; G09G 2300/0819; G09G 2300/0852; G09G 2300/0861

(57) ABSTRACT

A display device includes: a substrate; a first electrode on the substrate; a light emitting layer on the first electrode; a pixel defining layer on the light emitting layer; and a second electrode on the light emitting layer. First and second opposite sides of the light emitting layer are located on the pixel defining layer, and have straight line shapes that are inclined at an angle with respect to an upper surface of the pixel defining layer.

### CROSS-REFERENCE TO RELATED APPLICATION

The present application claims priority to and the benefit of Korean Patent Application No. 10-2023-0142570, filed on Oct. 24, 2023, in the Korean Intellectual Property Office, the entire disclosure of which is incorporated by reference herein.

### BACKGROUND

### 1. Field

Aspects of embodiments of the present disclosure relate to a display device, and a method for fabricating the display device.

### 2. Description of the Related Art

A head mounted display (HMD) is a display device for displaying images, and is worn on a user's head in the form of glasses or a helmet so that a focus is formed at a distance close to the user's eyes. For example, the head mounted display may implement virtual reality (VR) or augmented reality (AR).

The head mounted display enlarges and displays an image displayed by the display device, which may be small in size, by using a plurality of lenses. Therefore, it may be desirable for the display device that is applied to the head mounted display to provide an image of a high resolution, for example, such as an image having a resolution of 3000 Pixels per Inch (PPI) or more. As such, an Organic Light Emitting Diode on Silicon (OLEDoS), which is a small-sized organic light emitting display device having a high resolution, may be used as a display device that is applied to a head mounted display. The OLEDoS is a device that includes an organic light emitting diode (OLED) on a semiconductor wafer substrate on which a Complementary Metal Oxide Semiconductor (CMOS) is disposed to display images.

The above information disclosed in this Background section is for enhancement of understanding of the background of the present disclosure, and therefore, it may contain information that does not constitute prior art.

### SUMMARY

Embodiments of the present disclosure may be directed to a display device capable of suppressing an occurrence of a lateral leakage current between adjacent light emitting layers, and a method for fabricating the display device.

However, the present disclosure is not limited to the above aspects and features, and the above and other aspects and features will be set forth, in part, in the description that follows, and in part, may be apparent from the description, or may be learned by practicing one or more of the presented embodiments of the present disclosure.

According to one or more embodiments of the present disclosure, a display device includes: a substrate; a first electrode on the substrate; a light emitting layer on the first electrode; a pixel defining layer on the light emitting layer; and a second electrode on the light emitting layer. First and second opposite sides of the light emitting layer are located on the pixel defining layer, and have straight line shapes that are inclined at an angle with respect to an upper surface of the pixel defining layer.

In an embodiment, an angle between the upper surface of the pixel defining layer and the first side of the light emitting layer may be greater than 60° and smaller than or equal to 90°, and an angle between the upper surface of the pixel defining layer and the second side of the light emitting layer may be greater than 60° and smaller than or equal to 90°.

In an embodiment, a distance between the first side of the light emitting layer and the second side of the light emitting layer may gradually decrease in a direction away from the pixel defining layer.

In an embodiment, the display device may further include a first functional layer between the first electrode and the light emitting layer.

In an embodiment, first and second opposite sides of the first functional layer may be located on the pixel defining layer, and may have straight line shapes inclined at an angle with respect to the upper surface of the pixel defining layer.

In an embodiment, an angle between the upper surface of the pixel defining layer and the first side of the first functional layer may be greater than 60° and smaller than or equal to 90°, and an angle between the upper surface of the pixel defining layer and the second side of the first functional layer may be greater than 60° and smaller than or equal to 90°.

In an embodiment, a distance between the first side of the first functional layer and the second side of the first functional layer may gradually decrease in a direction away from the pixel defining layer.

In an embodiment, the first functional layer may include: a hole injection layer on the first electrode; and a hole transport layer on the hole injection layer.

In an embodiment, the display device may further include a second functional layer between the light emitting layer and the second electrode.

In an embodiment, first and second opposite sides of the second functional layer may be located on the pixel defining layer, and the first and second sides of the second functional layer may have straight line shapes inclined at an angle with respect to the upper surface of the pixel defining layer.

In an embodiment, an angle between the upper surface of the pixel defining layer and the first side of the second functional layer may be greater than 60° and smaller than or equal to 90°, and an angle between the upper surface of the pixel defining layer and the second side of the second functional layer may be greater than 60° and smaller than or equal to 90°.

In an embodiment, a distance between the first side of the second functional layer and the second side of the second functional layer may gradually decrease in a direction away from the pixel defining layer.

In an embodiment, the second functional layer may include a buffer layer on the light emitting layer.

In an embodiment, the display device may further include a common buffer layer between the second functional layer and the second electrode.

In an embodiment, the display device may further include a first functional layer between the first electrode and the light emitting layer, and the common buffer layer may be located on the first and second sides of the light emitting layer, first and second sides of the first functional layer, and first and second sides of the second functional layer.

In an embodiment, the display device may further include an electron transport layer between the common buffer layer and the second electrode.

In an embodiment, in a plan view, the electron transport layer may be located on the common buffer layer to surround the light emitting layer.

In an embodiment, the display device may further include an encapsulation layer on the second electrode.

In an embodiment, the pixel defining layer may include an inorganic layer.

According to one or more embodiments of the present disclosure, a method for fabricating a display device, includes: disposing a first electrode on a substrate; disposing a pixel defining layer on the first electrode; disposing a first functional layer, a light emitting layer, a second functional layer, and a sacrificial layer on an entire surface of the substrate including the pixel defining layer; disposing a photoresist pattern on the sacrificial layer to overlap with the first electrode; etching the first functional layer, the light emitting layer, the second functional layer, and the sacrificial layer by using the photoresist pattern as a mask so that the first functional layer, the light emitting layer, the second functional layer, and the sacrificial layer are disposed between the first electrode and the photoresist pattern; removing the photoresist pattern; and removing the etched sacrificial layer.

In an embodiment, the method may further include cleaning the substrate including the etched first functional layer, the etched light emitting layer, and the etched second functional layer.

In an embodiment, the method may further include: disposing the cleaned substrate in a vacuum chamber; and baking the substrate in the vacuum chamber.

In an embodiment, the method may further include disposing a common buffer layer on the second functional layer of the baked substrate in the vacuum chamber.

In an embodiment, the method may further include disposing an electron transport layer on the common buffer layer in the vacuum chamber.

In an embodiment, the method may further include disposing a second electrode on the electron transport layer in the vacuum chamber.

In an embodiment, in the etching of the first functional layer, the light emitting layer, the second functional layer, and the sacrificial layer by using the photoresist pattern as a mask, the first functional layer, the light emitting layer, the second functional layer, and the sacrificial layer may be etched by dry etching.

In an embodiment, in the removing of the etched sacrificial layer, the etched sacrificial layer may be removed by an etchant.

In an embodiment, the sacrificial layer may include at least one of aluminum or silver.

According to one or more embodiments of the present disclosure, an occurrence of a lateral leakage current between adjacent light emitting layers may be suppressed. Therefore, deterioration of an image quality, which may be caused by color mixture between adjacent pixels, may be minimized or reduced.

However, the present disclosure is not limited to the above aspects and features, and the above and other aspects and features of the present disclosure may be understood by those having ordinary skill in the art from the following detailed description with reference to the accompanying drawings.

### BRIEF DESCRIPTION OF THE DRAWINGS

The above and other aspects and features of the present disclosure will be

more clearly understood from the following detailed description of the illustrative, non-limiting embodiments with reference to the accompanying drawings, in which:

FIG. 1 is an exploded perspective view illustrating a display device according to an embodiment;

FIG. 2 is a layout view illustrating an example of a display panel shown in FIG. 1;

FIG. 3 is a block diagram illustrating a display device according to an embodiment;

FIG. 4 is an equivalent circuit diagram illustrating a first pixel according to an embodiment;

FIG. 5 is a plan view illustrating a display device according to an embodiment;

FIG. 6 is a cross-sectional view illustrating a display device taken along the line I-I′ of FIG. 5 according to an embodiment;

FIG. 7 is an enlarged view illustrating a first light emitting element of FIG. 6; and

FIGS. 8-24 are cross-sectional views illustrating a method of fabricating a display device according to one or more embodiments.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

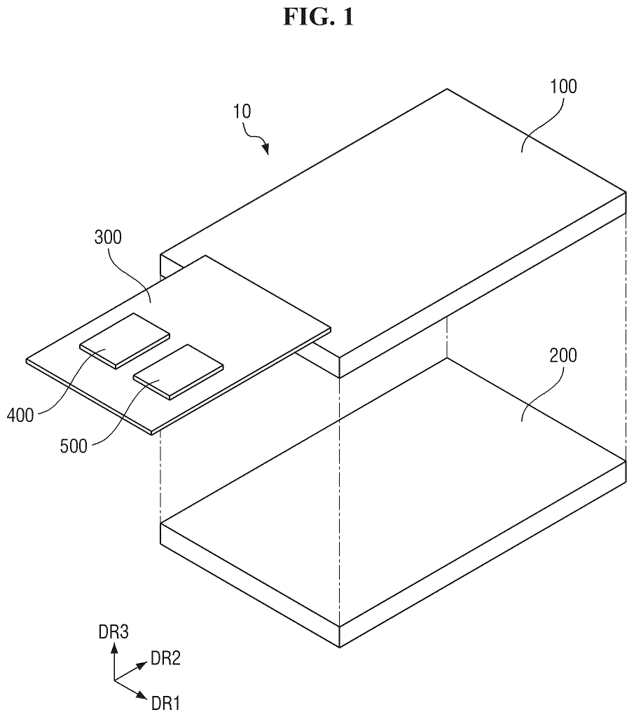

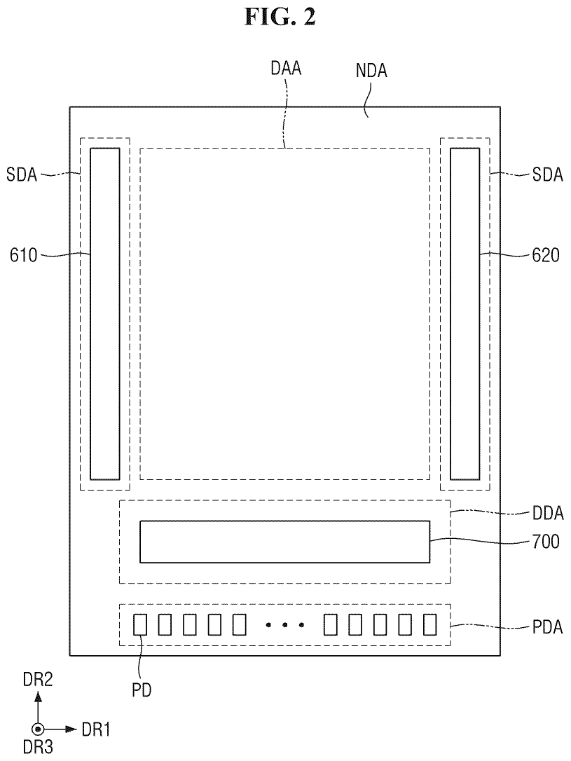

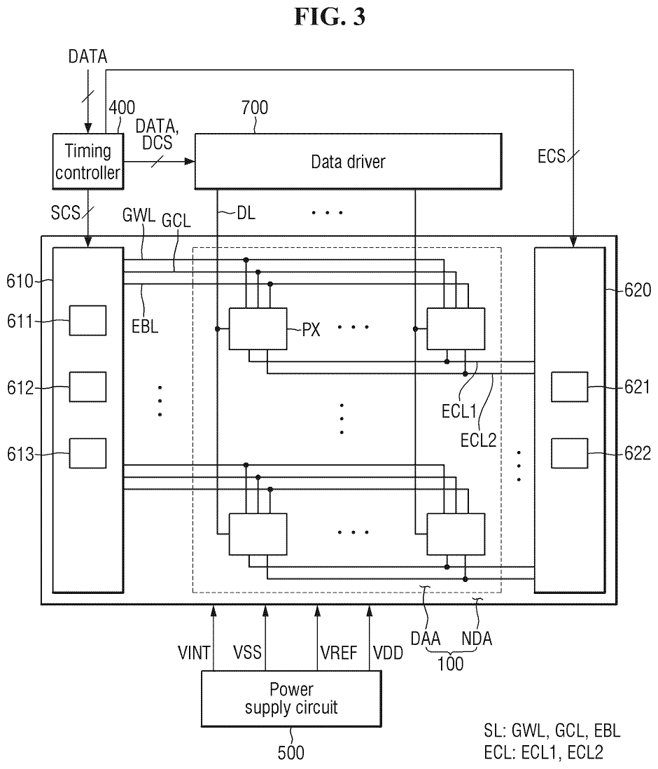

FIG. 1 is an exploded perspective view illustrating a display device according to an embodiment. FIG. 2 is a layout view illustrating an example of a display panel shown in FIG. 1. FIG. 3 is a block diagram illustrating a display device according to an embodiment.

Referring to FIGS. 1 and 2, a display device 10 according to an embodiment is a device for displaying a moving image and/or a still image. The display device 10 may be applied to a portable electronic device, such as a mobile phone, a smart phone, a tablet personal computer (PC), a mobile communication terminal, an electronic diary, an electronic book, a portable multimedia player (PMP), a navigator, and an ultra mobile PC (UMPC). For example, the display device 10 may be applied to a television, a laptop computer, a monitor, a signboard, or a display unit (e.g., a display) of an Internet of things (IoT) device. Also, the display device 10 may be applied to a smart watch, a watch phone, and a head mounted display (HMD) for implementing virtual reality (VR) and/or augmented reality (AR).

The display device 10 according to an embodiment includes a display panel 100, a heat dissipation layer 200, a circuit board 300, a timing control circuit 400, and a power supply circuit 500.

The display panel 100 may be formed in a planar shape similar to a rectangular shape. For example, the display panel 100 may have a planar shape like a rectangular shape having short sides extending in a first direction DR1, and long sides extending in a second direction DR2 crossing the first direction DR1. A corner where the short side in the first direction DR1 and the long side in the second direction DR2 meet each other may be rounded to have a curvature (e.g., a predetermined curvature), or may be formed at a right angle. The planar shape of the display panel 100 may be formed to be similar to other polygonal shapes, a circular shape, or an oval shape without being limited to the rectangular shape. A planar shape of the display device 10 may follow the planar shape of the display panel 100, but the present disclosure is not limited thereto.

The display panel 100 includes a display area DAA for displaying an image, and a non-display area NDA that does not display an image, as shown in FIG. 2.

As shown in FIG. 3, the display area DAA includes a plurality of pixels PX, a plurality of scan lines SL, a plurality of emission control lines ECL, and a plurality of data lines DL.

Each of the plurality of pixels PX includes a light emitting element for emitting light. The plurality of pixels PX may be arranged in the form of a matrix along the first direction DR1 and the second direction DR2. The plurality of scan lines SL and the plurality of emission control lines ECL may be extended in the first direction DR1, and may be disposed along the second direction DR2. The plurality of data lines DL may be extended in the second direction DR2, and may be disposed along the first direction DR1.

The plurality of scan lines SL include a plurality of write scan lines GWL, a plurality of control scan lines GCL, and a plurality of bias scan lines EBL. The plurality of emission control lines ECL include a plurality of first emission control lines ECL1 and a plurality of second emission control lines ECL2.

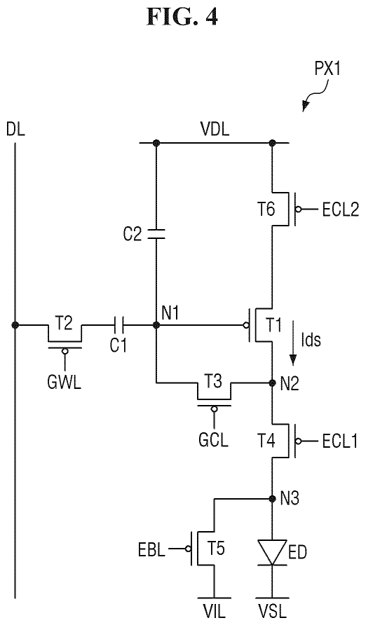

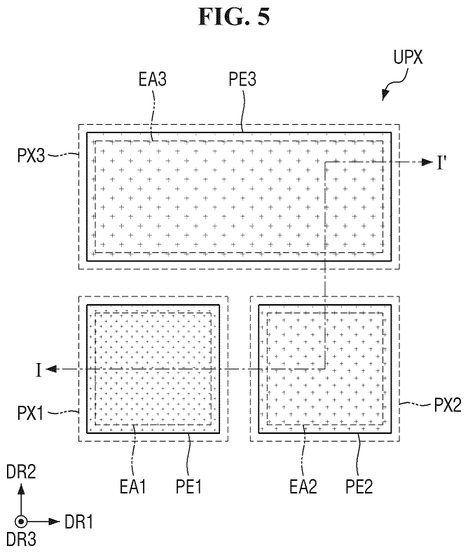

A plurality of unit pixels UPX (e.g., see FIG. 5) may include a plurality of pixels PX1, PX2, and PX3. The plurality of pixels PX1, PX2, and PX3 may include a plurality of pixel transistors as shown in FIG. 4. The plurality of pixel transistors may be formed by a semiconductor process, and may be disposed at (e.g., in or on) a semiconductor substrate. For example, the plurality of pixel transistors may be formed of a complementary metal oxide semiconductor (CMOS).

Each of the plurality of pixels PX1, PX2, and PX3 may be connected to any one of the plurality of write scan lines GWL, any one of the plurality of control scan lines GCL, any one of the plurality of bias scan lines EBL, any one of the plurality of first emission control lines ECL1, any one of the plurality of second emission control lines ECL2, and any one of the plurality of data lines DL. Each of the plurality of pixels PX1, PX2, and PX3 may receive a data voltage of the corresponding data line DL in accordance with a write scan signal of the corresponding write scan line GWL, and may allow a corresponding light emitting element to emit light in accordance with the data voltage.

The non-display area NDA includes a scan driving area SDA, a data driving area DDA, and a pad area PDA.

The scan driving area SDA may be an area in which a scan driver 610 and an emission driver 620 are disposed. Although FIG. 2 illustrates that the scan driver 610 is disposed at a left side of the display area DAA and the emission driver 620 is disposed at a right side of the display area DAA, the present disclosure is not limited thereto. For example, each of the scan driver 610 and the emission driver 620 may be disposed at both the left and right sides of the display area DAA.

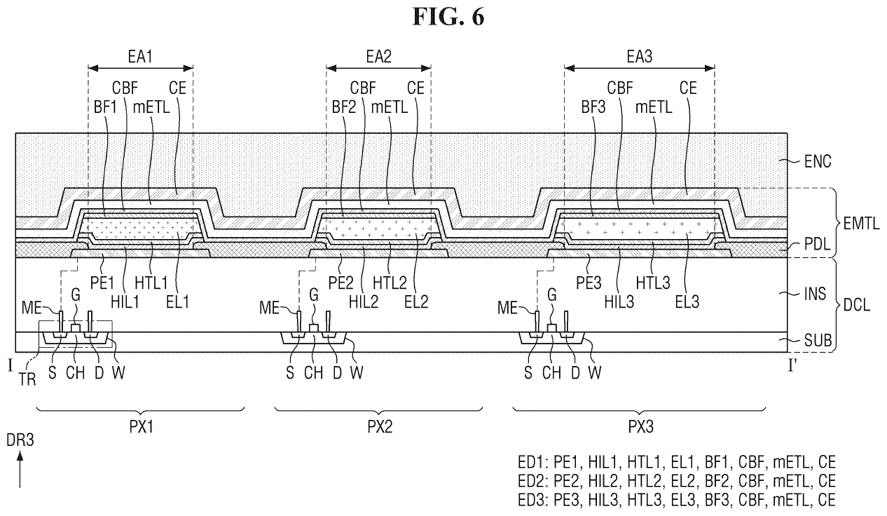

The scan driver 610 includes a plurality of scan transistors, and the emission driver 620 includes a plurality of light emitting transistors. The plurality of scan transistors and the plurality of light emitting transistors may be formed by a semiconductor process, and may be formed at (e.g., in or on) a semiconductor substrate (e.g., SUB of FIG. 6). For example, the plurality of scan transistors and the plurality of light emitting transistors may be formed of CMOS.

The scan driver 610 may include a write scan signal output unit (e.g., a write scan signal output circuit) 611, a control scan signal output unit (e.g., a control scan signal output circuit) 612, and a bias scan signal output unit (e.g., a bias scan signal output circuit) 613. Each of the write scan signal output unit 611, the control scan signal output unit 612, and the bias scan signal output unit 613 may receive a scan timing control signal SCS from the timing control circuit 400. The write scan signal output unit 611 may generate write scan signals in accordance with the scan timing control signal SCS of the timing control circuit 400, and may sequentially output the write scan signals to the write scan lines GWL. The control scan signal output unit 612 may generate control scan signals in accordance with the scan timing control signal SCS, and may sequentially output the control scan signals to the control scan lines GCL. The bias scan signal output unit 613 may generate bias scan signals in accordance with the scan timing control signal SCS, and may sequentially output the bias scan signals to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals in accordance with the emission timing control signal ECS, and may sequentially output the first emission control signals to the first emission control lines ECL1. The second emission control driver 622 may generate second emission control signals in accordance with the emission timing control signal ECS, and may sequentially output the second emission control signals to the second emission control lines ECL2.

The data driving area DDA may be an area in which a data driver 700 is disposed. The data driver 700 may include a plurality of data transistors. The plurality of data transistors may be formed by a semiconductor process, and may be formed at (e.g., in or on) the semiconductor substrate (e.g., SUB of FIG. 6). For example, the plurality of data transistors may be formed of CMOS.

The data driver 700 may receive digital video data DATA and a data timing control signal DCS from the timing control circuit 400. The data driver 700 converts the digital video data DATA into analog data voltages in accordance with the data timing control signal DCS, and outputs the analog data voltages to the data lines DL. In this case, the pixels PX1, PX2, and PX3 may be selected by the write scan signal of the scan driver 610, and the data voltages may be supplied to the selected pixels PX1, PX2, and PX3.

The pad area PDA includes a plurality of pads PD disposed along the first direction DR1. Each of the plurality of pads PD may be exposed without being covered by a cover layer and a polarizing plate.

The heat dissipation layer 200 may overlap with the display panel 100 in a third direction DR3, which is a thickness direction of the display panel 100. The heat dissipation layer 200 may be disposed on one surface of the display panel 100, for example, such as a rear surface of the display panel 100. The heat dissipation layer 200 serves to emit heat generated from the display panel 100. The heat dissipation layer 200 may include a metal layer, such as graphite, silver (Ag), copper (Cu), or aluminum (Al), which has high thermal conductivity.

The circuit board 300 may be electrically connected to the plurality of pads PD of the pad area PDA of the display panel 100 by using a conductive adhesive member, such as an anisotropic conductive film. The circuit board 300 may be a flexible printed circuit board or a flexible film, which includes a flexible material. Although FIG. 1 illustrates that the circuit board 300 is unfolded, the circuit board 300 may be bent. In this case, one end of the circuit board 300 may be disposed on the rear surface of the display panel 100. The one end of the circuit board 300 may be opposite to the other end of the circuit board 300 that is connected to the plurality of pads PD of the pad area PDA of the display panel 100 by using the conductive adhesive member.

The timing control circuit 400 may receive digital video data and timing signals from the outside. The timing control circuit 400 may generate the scan timing control signal SCS, the emission timing control signal ECS, and the data timing control signal DCS, which are used for controlling the display panel 100, in accordance with the timing signals. The timing control circuit 400 may output the scan timing control signal SCS to the scan driver 610, and may output the emission timing control signal ECS to the emission driver 620. The timing control circuit 400 may output the digital video data and the data timing control signal DCS to the data driver 700.

The power supply circuit 500 may generate a plurality of panel driving voltages in accordance with a power voltage from the outside. For example, the power supply circuit 500 may generate a first driving voltage VSS, a second driving voltage VDD, and a third driving voltage VINT, and may supply them to the display panel 100.

The first driving voltage VSS, the second driving voltage VDD, and the third driving voltage VINT will be described in more detail below with reference to FIG. 4.

Each of the timing control circuit 400 and the power supply circuit 500 may be formed of an integrated circuit (IC), and may be attached to one surface of the circuit board 300. The scan timing control signal SCS, the emission timing control signal ECS, the digital video data DATA, and the data timing control signal DCS of the timing control circuit 400 may be supplied to the display panel 100 through the circuit board 300. The first driving voltage VSS, the second driving voltage VDD, and the third driving voltage VINT of the power supply circuit 500 may be supplied to the display panel 100 through the circuit board 300.

FIG. 4 is an equivalent circuit diagram illustrating a first pixel according to an embodiment.

Referring to FIG. 4, the first pixel PX1 may be connected to the write scan line GWL, the control scan line GCL, the bias scan line EBL, the first emission control line ECL1, the second emission control line ECL2, and the data line DL. The first pixel PX1 may also be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. In other words, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than that of the third driving voltage VINT. The second driving voltage VDD may be higher than the third driving voltage VINT.

The first pixel PX1 includes a plurality of transistors T1 to T6, a light emitting element ED, a first capacitor C1, and a second capacitor C2.

The light emitting element ED emits light in accordance with a driving current Ids flowing through a channel of the first transistor T1. The amount of light emitted from the light emitting element ED may be proportional to the driving current Ids. The light emitting element ED may be disposed between the fourth transistor T4 and the first driving voltage line VSL. A first electrode of the light emitting element ED may be connected to a drain electrode of the fourth transistor T4, and a second electrode of the light emitting element ED may be connected to the first driving voltage line VSL. The first electrode of the light emitting element ED may be an anode electrode (e.g., a pixel electrode), and the second electrode of the light emitting element ED may be a cathode electrode (e.g., a common electrode CE). The light emitting element ED may be an organic light emitting diode that includes the first electrode, the second electrode, and an organic light emitting layer disposed between the first electrode and the second electrode, but the present disclosure is not limited thereto. For example, the light emitting element ED may be an inorganic light emitting element that includes the first electrode, the second electrode, and an inorganic semiconductor disposed between the first electrode and the second electrode. In this case, the light emitting element ED may be a micro light emitting diode.

The first transistor T1 may be a driving transistor for controlling a source-drain current (hereinafter, referred to as the driving current Ids) flowing between a source electrode and a drain electrode of the first transistor T1 in accordance with a voltage applied to a gate electrode of the first transistor T1. The first transistor T1 includes the gate electrode connected to a first node N1, the source electrode connected to a drain electrode of the sixth transistor T6, and the drain electrode connected to a second node N2.

The second transistor T2 may be disposed between one electrode of the first capacitor C1 and the data line DL. The second transistor T2 may be turned on by the write scan signal of the write scan line GWL to connect the one electrode of the first capacitor C1 to the data line DL. As a result, a data voltage of the data line DL may be applied to the one electrode of the first capacitor C1. The second transistor T2 includes a gate electrode connected to the write scan line GWL, a source electrode connected to the data line DL, and a drain electrode connected to the one electrode of the first capacitor C1.

The third transistor T3 may be disposed between the first node N1 and the second node N2. The third transistor T3 is turned on by the write control signal of the write control line GCL to connect the first node N1 to the second node N2. Because the gate electrode and the source electrode of the first transistor T1 are connected to each other by the third transistor T3, the first transistor T1 may operate like a diode (e.g., may be diode-connected). The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line ECL1 to connect the second node N2 to the third node N3. Therefore, the driving current Ids of the first transistor T1 may be supplied to the light emitting element ED. The fourth transistor T4 includes a gate electrode connected to the first emission control line ECL1, a source electrode connected to the second node N2, and a drain electrode connected to the third node N3.

The fifth transistor T5 may be disposed between the third node N3 and the third driving voltage line VIL. The fifth transistor T5 may be turned on by the bias scan signal of the bias scan line EBL to connect the third node N3 to the third driving voltage line VIL. As a result, the third driving voltage VINT of the third driving voltage line VIL may be applied to the first electrode of the light emitting element ED. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 may be turned on by the second emission control signal of the second emission control line ECL2 to connect the source electrode of the first transistor T1 to the second driving voltage line VDL. As a result, the second driving voltage VDD of the second driving voltage line VDL may be applied to the source electrode of the first transistor T1. The sixth transistor T6 includes a gate electrode connected to the second emission control line ECL2, a source electrode connected to the second driving voltage line VDL, and a drain electrode connected to the source electrode of the first transistor T1.

The first capacitor C1 is formed between the first node N1 and the drain electrode of the second transistor T2. The first capacitor C1 includes one electrode connected to the drain electrode of the second transistor T2, and another electrode connected to the first node N1.

The second capacitor C2 is formed between the gate electrode of the first transistor T1 and the second driving voltage line VDL. The second capacitor C2 includes one electrode connected to the gate electrode of the first transistor T1. and another electrode connected to the second driving voltage line VDL.

The first node N1 is a contact point of the gate electrode of the first transistor T1, the drain electrode of the third transistor T3, the other electrode of the first capacitor C1, and the one electrode of the second capacitor C2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element ED.

Each of the first to sixth transistors T1 to T6 may be a metal-oxide- semiconductor field effect transistor (MOSFET). For example, each of the first to sixth transistors T1 to T6 may be a P-type MOSFET, but the present disclosure is not limited thereto. For example, each of the first to sixth transistors T1 to T6 may be an N-type MOSFET. As another example, each of some of the first to sixth transistors T1 to T6 may be a P-type MOSFET, and each of the other remaining transistors thereamong may be an N-type MOSFET.

Although FIG. 4 illustrates that the first pixel PX1 includes six transistors T1 to T6 and two capacitors C1 and C2, the present disclosure is not limited to the equivalent circuit view of the first pixel PX1 shown in FIG. 4. For example, the number of transistors and the number of capacitors of the first pixel PX1 may be various modified as needed or desired as would be understood by those having ordinary skill in the art.

Also, the equivalent circuit view of the second pixel PX2 and the equivalent circuit view of the third pixel PX3 may be the same or substantially the same as the equivalent circuit view of the first pixel PX1 described above with reference to FIG. 4. Therefore, redundant description of the equivalent circuit view of the second pixel PX2 and the equivalent circuit view of the third pixel PX3 will not be repeated.

FIG. 5 is a plan view illustrating a display device according to an embodiment.

As shown in FIG. 5, the display device 10 may include a first pixel PX1, a second pixel PX2, and a third pixel PX3. The first pixel PX1, the second pixel PX2, and the third pixel PX3 may form one unit pixel UPX. In other words, the unit pixel UPX may include a first pixel PX1, a second pixel PX2, and a third pixel PX3, which are disposed to be adjacent to one another.

The first to third pixels PX1 to PX3 of the unit pixel UPX may be pixels for providing light of different colors (e.g., wavelengths) from each other. For example, the first pixel PX1 may provide light of a first color, the second pixel PX2 may provide light of a second color, and the third pixel PX3 may provide light of a third color. The first color may be any one of red, green, or blue, the second color may be any one color different from the first color from among red, green, and blue, and the third color may be any one remaining color different from the first color and the second color from among red, green, and blue.

The first pixel PX1 may include a first pixel electrode PE1, the second pixel PX2 may include a second pixel electrode PE2, and the third pixel PX3 may include a third pixel electrode PE3.

The first pixel electrode PE1, the second pixel electrode PE2, and the third pixel electrode PE3 may be disposed to be adjacent to one another. For example, the first pixel electrode PE1 and the second pixel electrode PE2 may be disposed to be adjacent to each other in the first direction DR1, the second pixel electrode PE2 and the third pixel electrode PE3 may be disposed to be adjacent to each other in the second direction DR2, and the third pixel electrode PE3 and the first pixel electrode PE1 may be disposed to be adjacent to each other in the second direction DR2.

The first to third pixel electrodes PE1 to PE3 may have different sizes from one another. For example, an area of the third pixel electrode PE3 may be larger than the sum of an area of the first pixel electrode PE1 and an area of the second pixel electrode PE2. In this case, the third pixel PX3 including the third pixel electrode PE3 may provide blue light, the first pixel PX1 including the first pixel electrode PE1 may provide red light, and the second pixel PX2 including the second pixel electrode PE2 may provide green light. When the third pixel PX3 provides blue light, the first pixel PX1 provides red light, and the second pixel PX2 provides green light, the area of the second pixel electrode PE2 may be larger than the area of the first pixel electrode PE1, and smaller than the area of the third pixel electrode PE3.

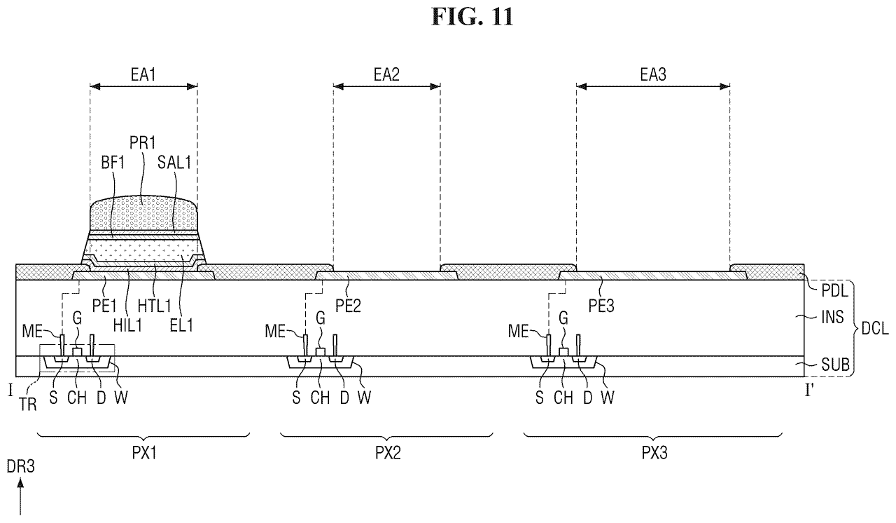

A portion (e.g., an edge) of the first pixel electrode PE1, a portion (e.g., an edge) of the second pixel electrode PE2, and a portion (e.g., an edge) of the third pixel electrode PE3 may be covered by a pixel defining layer (e.g., see PDL of FIG. 11), which will be described in more detail below. In other words, a portion (e.g., an edge) of the first pixel electrode PE1, a portion (e.g., an edge) of the second pixel electrode PE2, and a portion (e.g., an edge) of the third pixel electrode PE3 may partially overlap with the pixel defining layer PDL (e.g., see FIG. 11).

A first light emission area EA1, a second light emission area EA2, and a third light emission area EA3 may be defined by areas of the first pixel electrode PE1, the second pixel electrode PE2, and the third pixel electrode PE3, respectively, which are exposed without being covered by the pixel defining layer PDL. For example, the first light emission area EA1 may be a light emission area of the first pixel PX1 including the first pixel electrode PE1, the second light emission area EA2 may be a light emission area of the second pixel PX2 including the second pixel electrode PE2, and the third light emission area EA3 may be a light emission area of the third pixel PX3 including the third pixel electrode PE3.

FIG. 6 is a cross-sectional view illustrating a display device taken along the line I-I′ of FIG. 5 according to an embodiment.

As shown in FIG. 6, the display device 10 according to some embodiments may include a driving circuit layer DCL, a light emitting element layer EMTL, and an encapsulation layer ENC.

A substrate SUB may be a silicon substrate SUB, a germanium substrate SUB, or a silicon-germanium substrate SUB. The substrate SUB may be doped with first type impurities.

A well area W may be disposed at (e.g., in or on) the substrate SUB (e.g., inside the substrate SUB). The well area W may be an area doped with second type impurities. The second type impurities may be different from the first type impurities. For example, when the first type impurities are p-type impurities, the second type impurities may be n-type impurities. When the first type impurities are n-type impurities, the second type impurities may be p-type impurities.

A source area S, a drain area D, and a channel area CH of a transistor TR may be disposed in the well area W. For example, the source area S (e.g., a source electrode) and the drain area D (e.g., a drain electrode) of the transistor TR may be disposed in the well area W. Each of the source area S and the drain area D may be an area doped with the first type impurities. A gate electrode G of the transistor TR may overlap with the well area W, while crossing the well area W. In a plan view, the well area W crossing the gate electrode G may be defined as two areas, the source area S may be disposed in any one of the two areas, and the drain area D may be disposed in the other one of the two areas. In other words, in the well area W, the source area S and the drain area D may be disposed at both sides (e.g., opposite sides) of the gate electrode G, with the gate electrode G interposed therebetween. The channel area CH of the transistor may be disposed in an area of the well area W, which overlaps with the gate electrode G. The transistor TR shown in FIG. 6 may be, for example, the fourth transistor T4 illustrated in FIG. 4.

The source area S may include a first lightly doped impurity area having an impurity concentration relatively lower than that of the other portions of the source area S. In other words, a portion of the source area S may include impurities of a concentration lower than that of the other portions of the source area S. The drain area D may include a second lightly doped impurity area having an impurity concentration relatively lower than that of the other portions of the drain area D. In other words, a portion of the drain area D may include impurities of a concentration lower than that of the other portions of the drain area D.

The first lightly doped impurity area and the second lightly doped impurity area may be disposed to be adjacent to the channel area CH of the transistor TR. For example, the first lightly doped impurity area may be disposed to be adjacent to the channel area CH, thereby overlapping with a first sidewall disposed at one side of the gate electrode G. The second lightly doped impurity area may be disposed to be adjacent to the channel area CH, thereby overlapping with a second sidewall disposed at the other side of the gate electrode G. As described above, a distance between a heavily doped impurity area of the source area S and a heavily doped impurity area of the drain area D may be increased by the first lightly doped impurity area and the second lightly doped impurity area. Because the distance is increased, a length of the channel area CH may be increased. Therefore, a punch-through phenomena and a hot carrier phenomena due to a shorter channel may be avoided.

The source area S of each transistor TR may be connected to a pixel electrode of a corresponding light emitting layer through a metal layer ME.

An interlayer insulating layer INS may be disposed on the substrate SUB. The interlayer insulating layer INS may include a plurality of insulating layers that are stacked along the third direction DR3.

The light emitting element layer EMTL may be disposed on the interlayer insulating layer INS. The light emitting element layer EMTL may include, for example, a first light emitting element ED1, a second light emitting element ED2, and a third light emitting element ED3, which are disposed in respective light emission areas that are different from one another. For example, the first light emitting element ED1 of the light emitting element layer EMTL may be disposed in the first light emission area EA1, the second light emitting element ED2 of the light emitting element layer EMTL may be disposed in the second light emission area EA2, and the third light emitting element ED3 of the light emitting element layer EMTL may be disposed in the third light emission area EA3.

The first light emitting element ED1 may provide red light, the second light emitting element ED2 may provide green light, and the third light emitting element ED3 may provide blue light.

The first light emitting element ED1 may include a first pixel electrode PE1 (e.g., a first anode electrode), a first light emitting layer EL1, and a common electrode CE, which are stacked in the third direction DR3. The first light emitting element ED1 may further include a first hole injection layer HIL1 and a first hole transport layer HTL1, which are sequentially stacked along the third direction DR3 on the first pixel electrode PE1 between the first pixel electrode PE1 and the first light emitting layer EL1. In addition, the first light emitting element ED1 may further include a first buffer layer BF1, a common buffer layer CBF, and an electron transport layer mETL, which are sequentially stacked along the third direction DR3 on the first light emitting layer EL1 between the first light emitting layer EL1 and the common electrode CE.

The second light emitting element ED2 may include a second pixel electrode PE3 (e.g., a second anode electrode), a second light emitting layer EL2, and a common electrode CE, which are stacked in the third direction DR3. The second light emitting element ED2 may further include a second hole injection layer HIL2 and a second hole transport layer HTL2, which are sequentially stacked along the third direction DR3 on the second pixel electrode PE2 between the second pixel electrode PE2 and the second light emitting layer EL2. In addition, the second light emitting element ED2 may further include a second buffer layer BF2, a common buffer layer CBF, and an electron transport layer mETL, which are sequentially stacked along the third direction DR3 on the second light emitting layer EL2 between the second light emitting layer EL2 and the common electrode CE.

The third light emitting element ED3 may include a third pixel electrode PE3 (e.g., a third anode electrode), a third light emitting layer EL3, and a common electrode CE, which are stacked in the third direction DR3. The third light emitting element ED3 may further include a third hole injection layer HIL3 and a third hole transport layer HTL3, which are sequentially stacked along the third direction DR3 on the third pixel electrode PE3 between the third pixel electrode PE3 and the third light emitting layer EL3. In addition, the third light emitting element ED3 may further include a third buffer layer BF3, a common buffer layer CBF, and an electron transport layer mETL, which are sequentially stacked along the third direction DR3 on the third light emitting layer EL3 between the third light emitting layer EL3 and the common electrode CE.

The common buffer layer CBF, the electron transport layer mETL, and the common electrode CE may be common layers that are commonly used for each of the light emitting elements ED1 to ED3. In other words, the plurality of light emitting elements ED1 to ED3 of the light emitting element layer EMTL may share the common buffer layer CBF, the electron transport layer mETL, and the common electrode CE with each other.

Each of the light emitting layers EL1 to EL3 may include an organic material to emit a desired color (e.g., a predetermined color). For example, the organic material layer may include a host and a dopant. The organic material layer may include a suitable material for emitting light of a desired color (e.g., a predetermined color), and may be formed by using a phosphorescent material or a fluorescent material.

For example, the first light emitting layer EL1 may provide light of a first color (e.g., red). As such, the organic material layer of the first light emitting layer EL1 may include a host material containing carbazole biphenyl (CBP) or 1,3-bis (carbazol-9-yl (mCP), and may be a phosphorescent material including a dopant containing at least one selected from PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium), and/or PtOEP (octaethylporphyrin platinum). As another example, the organic material layer of the third light emitting layer EL3 of the third light emission area EA3 may be a fluorescent material containing PBD:Eu(DBM)3(Phen) or perylene, but the present disclosure is not limited thereto.

The second light emitting layer EL2 may provide light of a second color (e.g., green). As such, the organic material layer of the second light emitting layer EL2 may include a host material containing CBP or mCP, and may be a phosphorescent material including a dopant material containing Ir(ppy)3(fac tris(2-phenylpyridine)iridium). As another example, the organic material layer of the second light emitting layer EL2 of the second light emission area EA2 that emits light of the second color may be a fluorescent material containing Alq3(tris(8-hydroxyquinolino)aluminum), but the present disclosure is not limited thereto.

The third light emitting layer EL3 may provide light of a third color (e.g., blue). As such, the organic material layer of the third light emitting layer EL3 may include a host material containing CBP or mCP, and may be a phosphorescent material including a dopant material containing (4,6-F2ppy)2Irpic or L2BD111, but the present disclosure is not limited thereto.

The first pixel electrode PE1, the second pixel electrode PE2, and the third pixel electrode PE3 may be connected to the source areas S of the transistors TR through contact holes of (e.g., penetrating) the interlayer insulating layer INS.

The first pixel electrode PE1 may be disposed to correspond to the first light emission area EA1, the second pixel electrode PE2 may be disposed to correspond to the second light emission area EA2, and the third pixel electrode PE3 may be disposed to correspond to the third light emission area EA3.

The pixel defining layer PDL may be disposed on the first pixel electrode PE1, the second pixel electrode PE2, and the third pixel electrode PE3.

The pixel defining layer PDL may define each of the light emission areas (e.g., the first light emission area EA1 of the first pixel PX1, the second light emission area EA2 of the second pixel PX2, and the third light emission area EA3 of the third pixel PX3) of the pixels PX1 to PX3. As such, the pixel defining layer PDL may be disposed to expose a partial area of each of the first pixel electrode PE1, the second pixel electrode PE2, and the third pixel electrode PE3. The pixel defining layer PDL may cover edges of the first pixel electrode PE1, the second pixel electrode PE2, and the third pixel electrode PE3. The pixel defining layer PDL may be formed of an inorganic layer. The pixel defining layer PDL may be formed of an organic layer, such as an acryl resin, an epoxy resin, a phenolic resin, a polyamide resin, or a polyimide resin.

The hole injection layer may be disposed on each of the pixel electrodes PE1, PE2, and PE3. For example, the first hole injection layer HIL1 may be disposed on the first pixel electrode PE1, the second hole injection layer HIL2 may be disposed on the second pixel electrode PE2, and the third hole injection layer HIL3 may be disposed on the third pixel electrode PE3.

The hole transport layer may be disposed on each of the hole injection layers HIL1 to HIL3. For example, the first hole transport layer HTL1 may be disposed on the first hole injection layer HIL1, the second hole transport layer HTL2 may be disposed on the second hole injection layer HIL2, and the third hole transport layer HTL3 may be disposed on the third hole injection layer HIL3.

The light emitting layer may be disposed on each of the hole transport layers HTL1 to HTL3. For example, the first light emitting layer EL1 may be disposed on the first hole transport layer HTL1, the second light emitting layer EL2 may be disposed on the second hole transport layer HTL2, and the third light emitting layer EL3 may be disposed on the third hole transport layer HTL3.

The buffer layer may be disposed on each of the light emitting layers EL1 to EL3. For example, the first buffer layer BF1 may be disposed on the first light emitting layer EL1, the second buffer layer BF2 may be disposed on the second light emitting layer EL2, and the third buffer layer BF3 may be disposed on the third light emitting layer EL3. The first buffer layer BF1, the second buffer layer BF2, and the third buffer layer BF3 are physically separated from one another.

The common buffer layer CBF may be disposed on each of the buffer layers BF1 to BF3. For example, the common buffer layer CBF may overlap with the first buffer layer BF1, the second buffer layer BF2, the third buffer layer BF3, the first pixel electrode PE1, the second pixel electrode PE2, the third pixel electrode PE3, the first light emission area EA1, the second light emission area EA2, the third light emission area EA3, and the pixel defining layer PDL. In an embodiment, the common buffer layer CBF may be further disposed on first and second sides of each of the light emitting layers EL1 to EL3, first and second sides of each of the hole injection layers HIL1 to HIL3, first and second sides of each of the hole transport layers HTL1 to HTL3, and first and second sides of each of the buffer layers BF1 to BF3.

The electron transport layer mETL may be disposed on the common buffer layer CBF. For example, the electron transport layer mETL may be disposed on the common buffer layer CBF to overlap with the first pixel electrode PE1, the second pixel electrode PE2, the third pixel electrode PE3, the first light emission area EA1, the second light emission area EA2, the third light emission area EA3, and the pixel defining layer PDL. In an embodiment, the electron transport layer mETL may be disposed on the common buffer layer CBF to surround (e.g., around peripheries of) the first light emitting layer EL1, the second light emitting layer EL2, and the third light emitting layer EL3. For example, in a plan view, the electron transport layer mETL may surround (e.g., around a periphery of) each of the first light emitting layer EL1, the second light emitting layer EL2, and the third light emitting layer EL3. Therefore, an occurrence of a lateral leakage current between adjacent light emitting layers may be suppressed. Accordingly, deterioration of an image quality due to color mixture between the adjacent pixels may be minimized or reduced.

The common electrode CE may be disposed on the electron transport layer mETL. For example, the common electrode CE may be disposed on the electron transport layer mETL to overlap with the first pixel electrode PE1, the second pixel electrode PE2, the third pixel electrode PE3, the first light emission area EA1, the second light emission area EA2, the third light emission area EA3, and the pixel defining layer PDL. In a top emission structure, the common electrode CE may be formed of a transparent conductive material (TCO), such as indium tin oxide (ITO) and/or indium zinc oxide (IZO), or a semi-transmissive conductive material, such as magnesium (Mg), silver (Ag), or a suitable alloy of magnesium (Mg) and silver (Ag). When the common electrode CE is formed of a semi-transmissive conductive material, light emission efficiency may be enhanced by a micro cavity.

The encapsulation layer ENC may be disposed on the common electrode CE. The encapsulation layer ENC may cover an upper surface and sides of the light emitting element layer EMTL, and may protect the light emitting element layer EMTL. The encapsulation layer ENC may include at least one inorganic layer and at least one organic layer to encapsulate the light emitting element layer EMTL. The encapsulation layer ENC may include at least one inorganic layer to prevent or substantially prevent oxygen and/or moisture from being permeated into the light emitting element layer EMTL. The encapsulation layer ENC may also include at least one organic layer to protect the light emitting element layer EMTL from particles such as dust. For example, the encapsulation layer ENC may include a first encapsulation inorganic layer, an encapsulation organic layer, and a second encapsulation inorganic layer, which may be sequentially stacked along the third direction DR3 on the common electrode CE. For example, the first encapsulation inorganic layer may be disposed on the common 1 electrode CE, the encapsulation organic layer may be disposed on the first encapsulation inorganic layer, and the second encapsulation inorganic layer may be disposed on the encapsulation organic layer. The first encapsulation inorganic layer and the second encapsulation inorganic layer may be formed of a multi-layered structure in which one or more inorganic layers of a silicon nitride layer, a silicon oxynitride layer, a silicon oxide layer, a titanium oxide layer, and/or an aluminum oxide layer are alternately stacked. The encapsulation organic layer may be an organic layer, such as an acryl resin, an epoxy resin, a phenolic resin, a polyamide resin, and/or a polyimide resin.

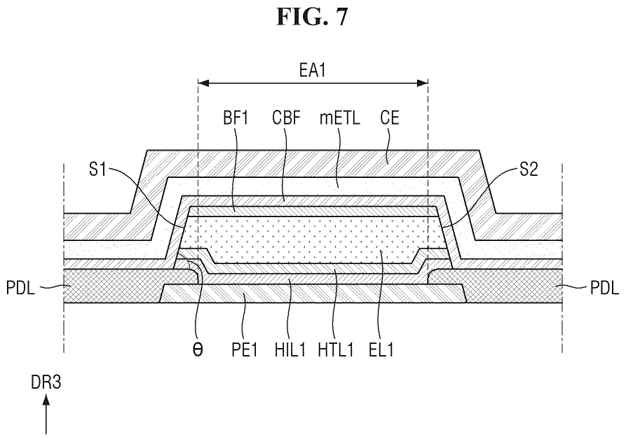

FIG. 7 is an enlarged view illustrating the first light emitting element ED1 of FIG. 6.

Referring to FIG. 7, a first side S1 and a second side S2 of the first light emitting layer EL1, which are opposite to each other, may be disposed on the pixel defining layer PDL. Each of the first side S1 and the second side S2 may have a straight line shape.

The first side S1 may have a straight line shape that is inclined at an angle (e.g., a predetermined angle) with respect to an upper surface of the pixel defining layer PDL. For example, an angle θ (e.g., an inner angle) formed by the upper surface of the pixel defining layer PDL and the first side S1 of the first light emitting layer EL1 may be greater than 60° and smaller than or equal to 90°. An angle formed by the upper surface of the pixel defining layer PDL and the second side S2 of the first light emitting layer EL1 may be the same as or different from the angle formed by the upper surface of the pixel defining layer PDL and the first side S1 of the first light emitting layer EL1. For example, the angle (e.g., an inner angle) formed by the upper surface of the pixel defining layer PDL and the second side S2 of the first light emitting layer EL1 may be greater than 60° and smaller than or equal to 90°.

A distance between the first side S1 and the second side S2 of the first light emitting layer EL1 may be gradually reduced in a direction away from the pixel defining layer PDL. For example, the distance between the first side S1 and the second side S2 may be gradually reduced along the third direction DR3.

Both sides (e.g., opposite sides) of a first functional layer (e.g., at least one of the first hole injection layer HIL1 or the first hole transport layer HTL1) disposed between the first light emitting layer EL1 and the first pixel electrode PE1 may have the same or substantially the same shape (e.g., a straight line shape) as those of the first side S1 and the second side S2 of the first light emitting layer EL1, respectively, as described above. In this case, the both sides of the first functional layer may be disposed on the pixel defining layer PDL. Further, a distance between the both sides of the first functional layer may be gradually reduced in a direction away from the pixel defining layer PDL. For example, a distance between the both sides of the first functional layer may be gradually reduced along the third direction DR3. An angle formed by the pixel defining layer PDL and one side of the functional layer may be greater than 60° and smaller than or equal to 90°. Also, an angle between the pixel defining layer PDL and the other side of the functional layer may be greater than 60° and smaller than or equal to 90°.

Both sides (e.g., opposite sides) of a second functional layer (e.g., the first buffer layer BF1) disposed between the first light emitting layer EL1 and the common buffer layer CBF may have the same or substantially the same shape (e.g., a straight line shape) as those of the first side S1 and the second side S2 of the first light emitting layer EL1, respectively, as described above. The both sides of the second functional layer may be disposed on the pixel defining layer PDL. A distance between the both sides of the second functional layer may be gradually reduced in a direction away from the pixel defining layer PDL. For example, a distance between the both sides of the second functional layer may be gradually reduced along the third direction DR3. An angle formed by the pixel defining layer PDL and one side of the second functional layer may be greater than 60° and smaller than or equal to 90°. Also, an angle formed by the pixel defining layer PDL and the other side of the second functional layer may be greater than 60° and smaller than or equal to 90°.

Both sides (e.g., opposite sides) of the second light emitting layer EL2 may have the same or substantially the same shape and angle (e.g., an inner angle greater than 60° and smaller than or equal to 90°) as those of the both sides S1 and S2 of the first light emitting layer EL1, respectively, as described above.

In addition, both sides (e.g., opposite sides) of the first functional layer (e.g., at least one of the second hole injection layer HIL2 or the second hole transport layer HTL2) of the second light emitting layer EL2 may have the same or substantially the same shape and angle (e.g., an inner angle greater than 60° and smaller than or equal to 90°) as those of the both sides S1 and S2 of the first light emitting layer EL1, respectively, as described above.

In addition, both sides (e.g., opposite sides) of the second functional layer (e.g., the second buffer layer BF2) of the second light emitting layer EL2 may have the same or substantially the same shape and angle (e.g., an inner angle greater than 60° and smaller than or equal to 90°) as those of the both sides S1 and S2 of the first light emitting layer EL1, respectively, as described above.

In addition, both sides (e.g., opposite sides) of the third light emitting layer EL3 may have the same or substantially the same shape and angle (e.g., an inner angle greater than 60° and smaller than or equal to 90°) as those of the both sides S1 and S2 of the first light emitting layer EL1, respectively, as described above.

In addition, both sides (e.g., opposite sides) of the first functional layer (e.g., at least one of the third hole injection layer HIL3 or the third hole transport layer HTL3) of the third light emitting layer EL3 may have the same or substantially the same shape and angle (e.g., an inner angle greater than 60° and smaller than or equal to 90°) as those of the both sides S1 and S2 of the first light emitting layer EL1, respectively, as described above.

In addition, both sides (e.g., opposite sides) of the second functional layer (e.g., the third buffer layer BF3) of the third light emitting layer EL3 may have the same or substantially the same shape and angle (e.g., an inner angle greater than 60° and smaller than or equal to 90°) as those of the both sides S1 and S2 of the first light emitting layer EL1, respectively, as described above.

As the both sides of the first light emitting layer EL1, the second light emitting layer EL2, the third light emitting layer EL3, the first hole injection layer HIL1, the second hole injection layer HIL2, the third hole injection layer HIL3, the first hole transport layer HTL1, the second hole transport layer HTL2, the third hole transport layer HTL3, the first buffer layer BF1, the second buffer layer BF2, and the third buffer layer BF3 have the shape and angle as described above, the light emitting layer, the first functional layer, and the second functional layer may not be disposed between the pixel defining layer PDL and the common buffer layer CBF directly on the pixel defining layer PDL. Therefore, a tail defect and a mask shadow defect due to the use of an existing fine metal mask (FMM) may not be generated. Accordingly, an occurrence of a lateral leakage current between adjacent light emitting layers may be suppressed. As a result, deterioration of an image quality due to color mixture between adjacent pixels may be minimized or reduced.

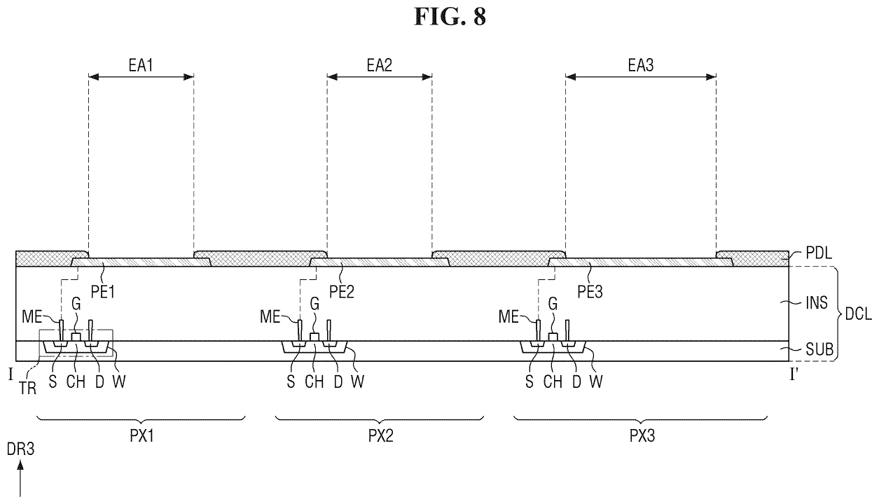

The both sides of the first light emitting layer EL1, the second light emitting layer EL2, the third light emitting layer EL3, the first hole injection layer HIL1, the second hole injection layer HIL2, the third hole injection layer HIL3, the first hole transport layer HTL1, the second hole transport layer HTL2, the third hole transport layer HTL3, the first buffer layer BF1, the second buffer layer BF2, and the third buffer layer BF3 may have the shape and angle as described above, because the aforementioned light emitting layers, hole injection layers, hole transport layers, and buffer layers may be formed by a photolithography process (e.g., an etching process using a photoresist pattern as a mask), which will be described in more detail below. Hereinafter, a method for fabricating a display device according to one or more embodiments will be described in more detail with reference to FIGS. 8 through 24.

FIGS. 8 through 24 are cross-sectional views illustrating a method of fabricating a display device according to one or more embodiments.

First, as shown in FIG. 8, the substrate SUB at (e.g., in or on) which the transistors TR are formed may be prepared. The interlayer insulating layer INS may be disposed on the substrate SUB. The first pixel electrode PE1, the second pixel electrode PE2, and the third pixel electrode PE3 may be disposed on the interlayer insulating layer INS. The first pixel electrode PE1 may be connected to the transistor TR of the first pixel PX1 through one or more contact holes passing through the interlayer insulating layer INS. The second pixel electrode PE2 may be connected to the transistor TR of the second pixel PX2 through one or more contact holes passing through the interlayer insulating layer INS. The third pixel electrode PE3 may be connected to the transistor TR of the third pixel PX3 through one or more contact holes passing through the interlayer insulating layer INS.

Next, as shown in FIG. 8, the pixel defining layer PDL may be disposed on the interlayer insulating layer INS, the first pixel electrode PE1, the second pixel electrode PE2, and the third pixel electrode PE3. A portion, except for each edge of the first pixel electrode PE1, the second pixel electrode PE2, and the third pixel electrode PE3, may be exposed by a corresponding opening of the pixel defining layer PDL. For example, the first light emission area EA1 of the first pixel PX1, the second light emission area EA2 of the second pixel PX2, and the third light emission area EA3 of the third pixel PX3 may be defined by the pixel defining layer PDL. According to a method for fabricating a display device according to an embodiment, because the light emitting layer and the like may be formed through a photolithography process without the use of the existing fine metal mask, the pixel defining layer PDL may not need to have a large thickness. Therefore, according to an embodiment, the pixel defining layer PDL may include (e.g., may be made of) an inorganic material capable of having a lower (e.g., a reduced) thickness.

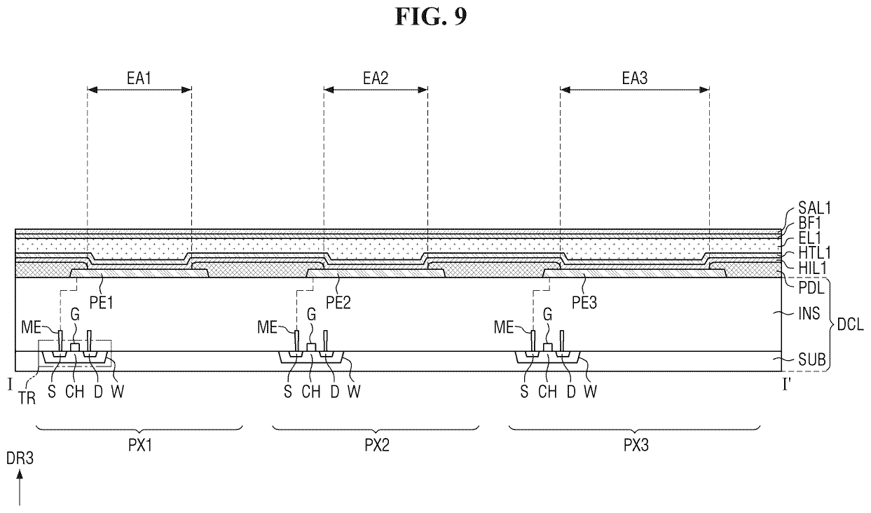

As shown in FIG. 9, the first hole injection layer HIL1, the first hole transport layer HTL1, the first light emitting layer EL1, the first buffer layer BF1, and a first sacrificial layer SAL1 may be sequentially disposed along the third direction DR3 on the first pixel electrode PE1, the second pixel electrode PE2, the third pixel electrode PE3, and the pixel defining layer PDL. For example, the first hole injection layer HIL1, the first hole transport layer HTL1, the first light emitting layer EL1, the first buffer layer BF1, and the first sacrificial layer SAL1 may be disposed on the entire or substantially entire surface of the substrate SUB.

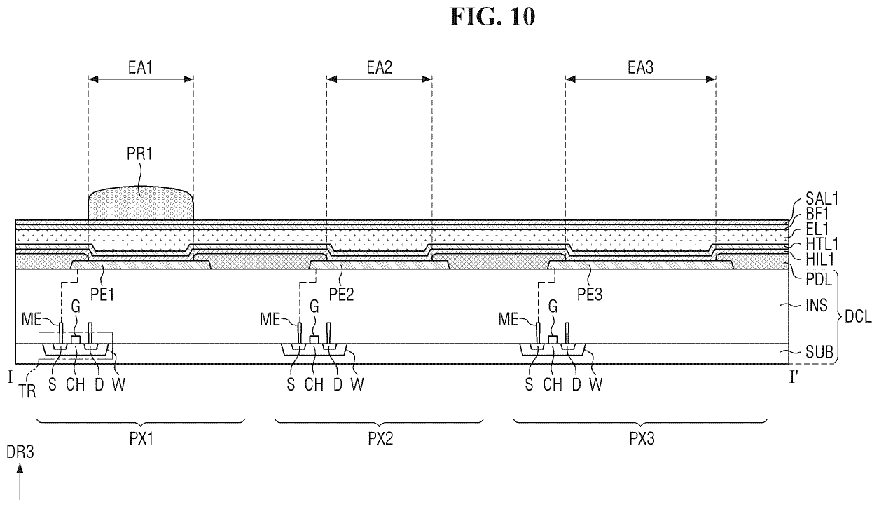

Next, as shown in FIG. 10, a first photoresist pattern PR1 may be disposed on the first sacrificial layer SAL1 to correspond to the first light emission area EA1 of the first pixel PX1.

Then, as shown in FIG. 11, an etching process may be performed using the first photoresist pattern PR1 as a mask. The etching process may be a dry etching process. The first sacrificial layer SAL1 may prevent or substantially prevent the first buffer layer BF1 therebelow from being damaged during the etching process. The first sacrificial layer SAL1 may include a metal. For example, the first sacrificial layer SAL1 may include at least one of aluminum or silver. A portion of the first hole injection layer HIL1, the first hole transport layer HTL1, the first light emitting layer EL1, the first buffer layer BF1, and the first sacrificial layer SAL1, which is not covered by the first photoresist pattern PR1, may be removed by the etching process as shown in FIG. 11. For example, the first hole injection layer HIL1, the first hole transport layer HTL1, the first light emitting layer EL1, the first buffer layer BF1, and the first sacrificial layer SAL1 may be patterned to be disposed between the first pixel electrode PE1 and the first photoresist pattern PR1 by the etching process.

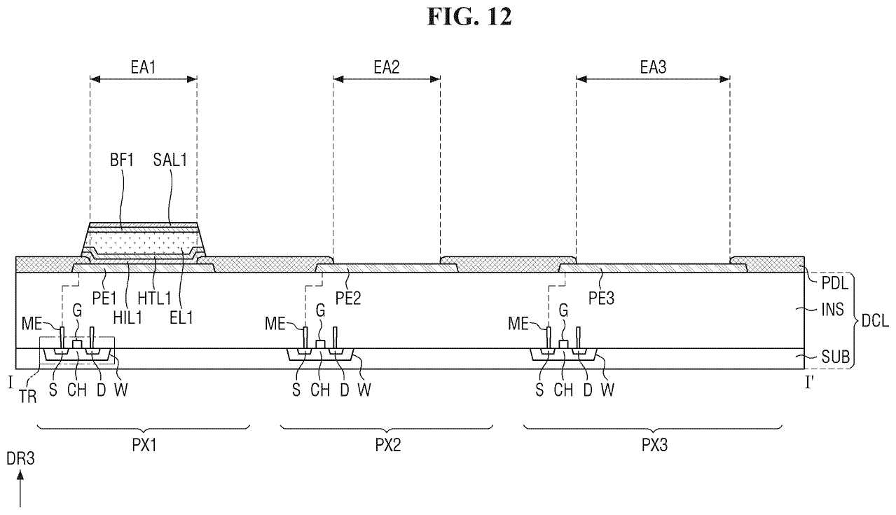

As shown in FIG. 12, the first photoresist pattern PR1 may be removed. For example, the first photoresist pattern PR1 may be removed by an ashing process.

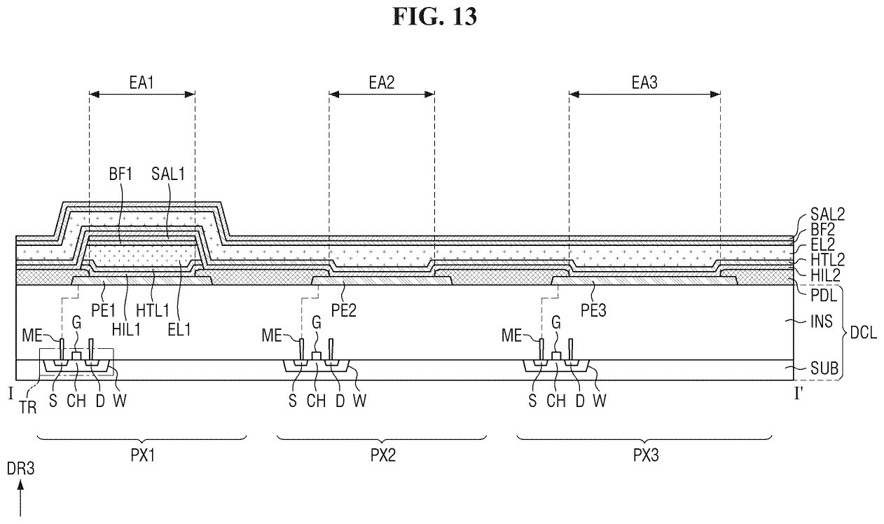

As shown in FIG. 13, the second hole injection layer HIL2, the second hole transport layer HTL2, the second light emitting layer EL2, the second buffer layer BF2, and a second sacrificial layer SAL2 may be sequentially disposed on the first sacrificial layer SAL1, the second pixel electrode PE2, the third pixel electrode PE3, and the pixel defining layer PDL along the third direction DR3. For example, the second hole injection layer HIL2, the second hole transport layer HTL2, the second light emitting layer EL2, the second buffer layer BF2, and the second sacrificial layer SAL2 may be disposed on the entire or substantially entire surface of the substrate SUB.

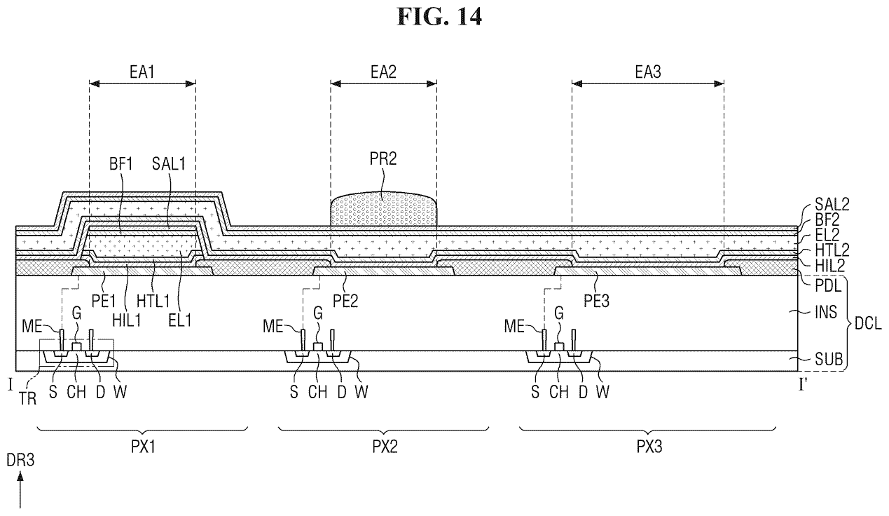

Next, as shown in FIG. 14, a second photoresist pattern PR2 may be disposed on the second sacrificial layer SAL2 to correspond to the second light emission area EA2 of the second pixel PX2.

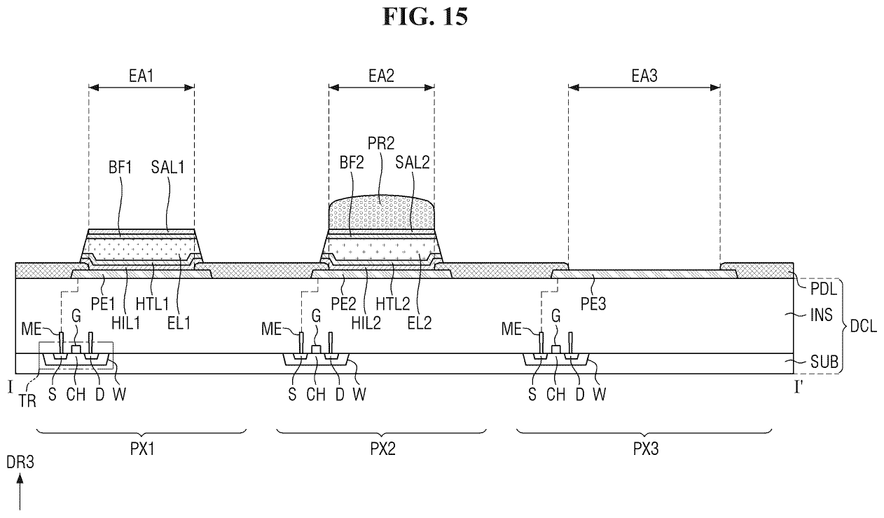

Then, as shown in FIG. 15, an etching process may be performed using the second photoresist pattern PR2 as a mask. The etching process may be a dry etching process. The second sacrificial layer SAL2 may prevent or substantially prevent the second buffer layer BF2 therebelow from being damaged during the etching process. The second sacrificial layer SAL2 may include a metal. For example, the second sacrificial layer SAL2 may include at least one of aluminum or silver. A portion of the second hole injection layer HIL2, the second hole transport layer HTL2, the second light emitting layer EL2, the second buffer layer BF2, and the second sacrificial layer SAL2, which is not covered by the second photoresist pattern PR2, may be removed by the etching process as shown in FIG. 15. For example, the second hole injection layer HIL2, the second hole transport layer HTL2, the second light emitting layer EL2, the second buffer layer BF2, and the second sacrificial layer SAL2 may be patterned to be disposed between the second pixel electrode PE2 and the second photoresist pattern PR2 by the etching process.

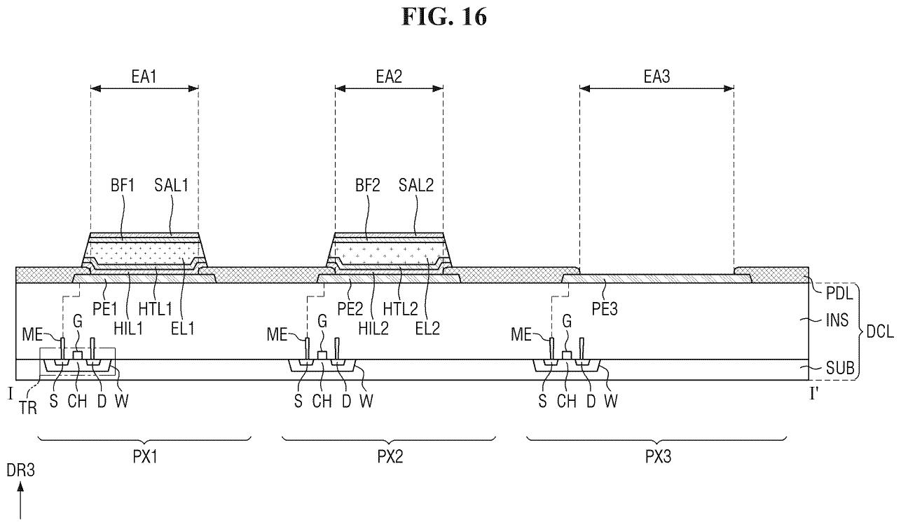

Next, as shown in FIG. 16, the second photoresist pattern PR2 may be removed. For example, the second photoresist pattern PR2 may be removed by an ashing process.

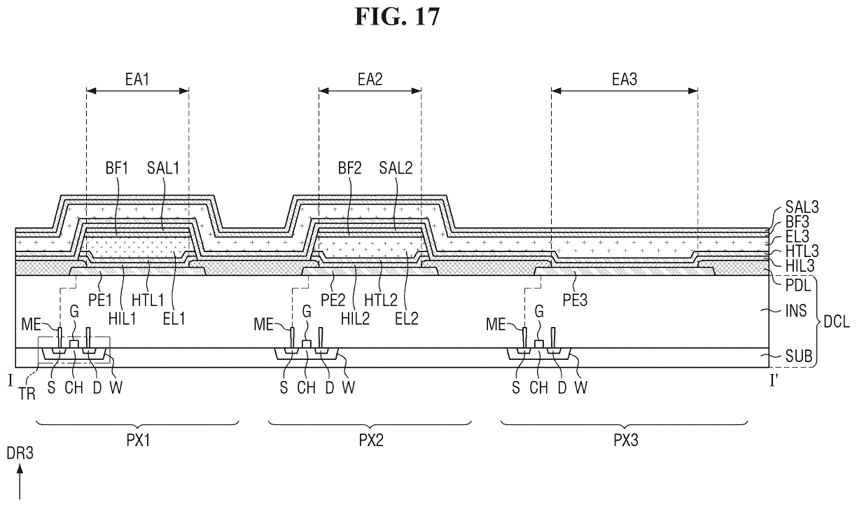

As shown in FIG. 17, the third hole injection layer HIL3, the third hole transport layer HTL3, the third light emitting layer EL3, the third buffer layer BF3, and a third sacrificial layer SAL3 may be sequentially disposed on the first sacrificial layer SAL1, the second sacrificial layer SAL2, the third pixel electrode PE3, and the pixel defining layer PDL along the third direction DR3. For example, the third hole injection layer HIL3, the third hole transport layer HTL3, the third light emitting layer EL3, the third buffer layer BF3, and the third sacrificial layer SAL3 may be disposed on the entire or substantially entire surface of the substrate SUB.

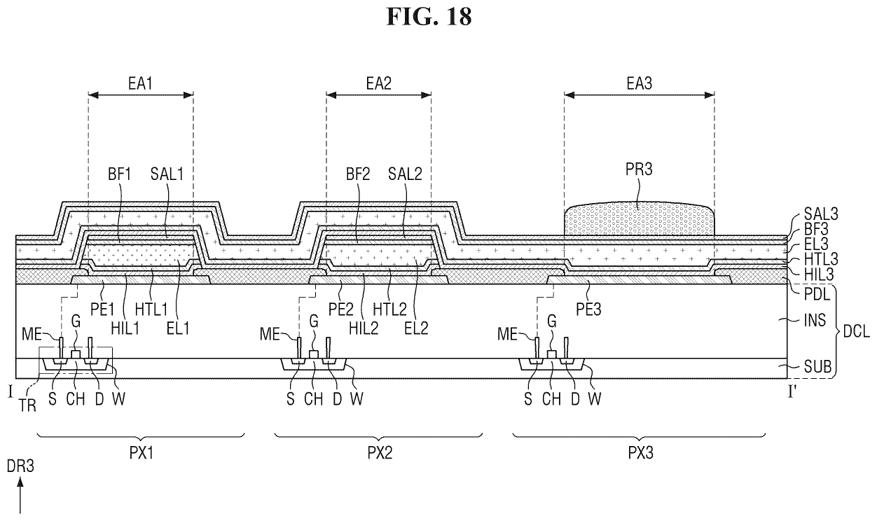

Next, as shown in FIG. 18, a third photoresist pattern PR3 may be disposed on the third sacrificial layer SAL3 to correspond to the third light emission area EA3 of the third pixel PX3.

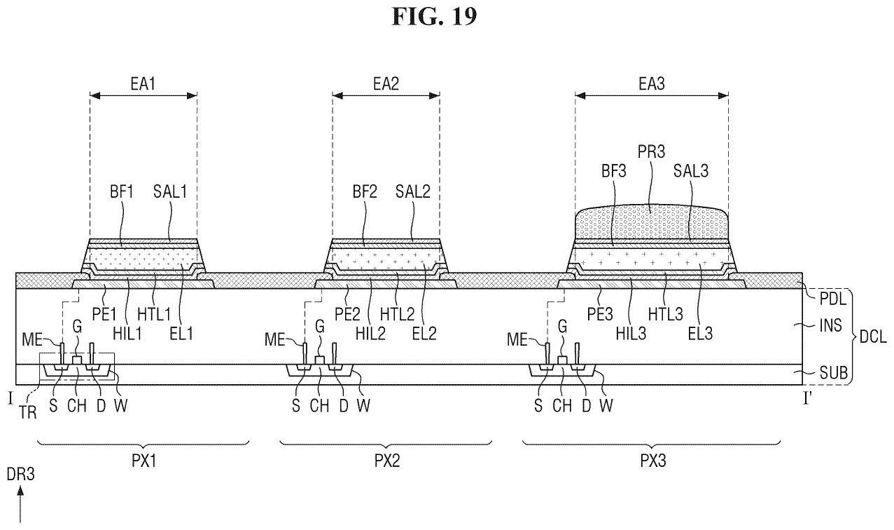

Then, as shown in FIG. 19, an etching process may be performed using the third photoresist pattern PR3 as a mask. The etching process may be a dry etching process. The third sacrificial layer SAL3 may prevent or substantially prevent the third buffer layer BF3 therebelow from being damaged during the etching process. The third sacrificial layer SAL3 may include a metal. For example, the third sacrificial layer SAL3 may include at least one of aluminum or silver. A portion of the third hole injection layer HIL3, the third hole transport layer HTL3, the third light emitting layer EL3, the third buffer layer BF3, and the third sacrificial layer SAL3, which is not covered by the third photoresist pattern PR3, may be removed by the etching process of FIG. 19. For example, the third hole injection layer HIL3, the third hole transport layer HTL3, the third light emitting layer EL3, the third buffer layer BF3, and the third sacrificial layer SAL3 may be patterned to be disposed between the third pixel electrode PE3 and the third photoresist pattern PR3 by the etching process.

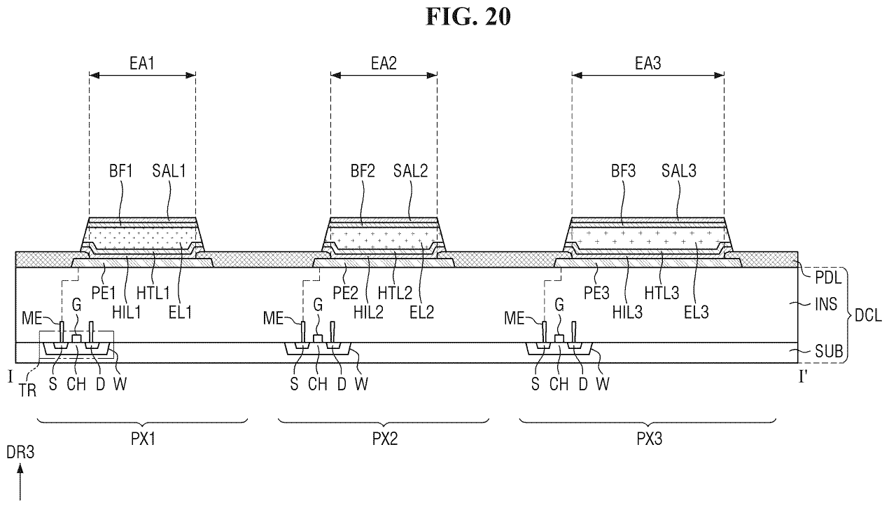

Next, as shown in FIG. 20, the third photoresist pattern PR3 may be removed. For example, the third photoresist pattern PR3 may be removed by an ashing process.

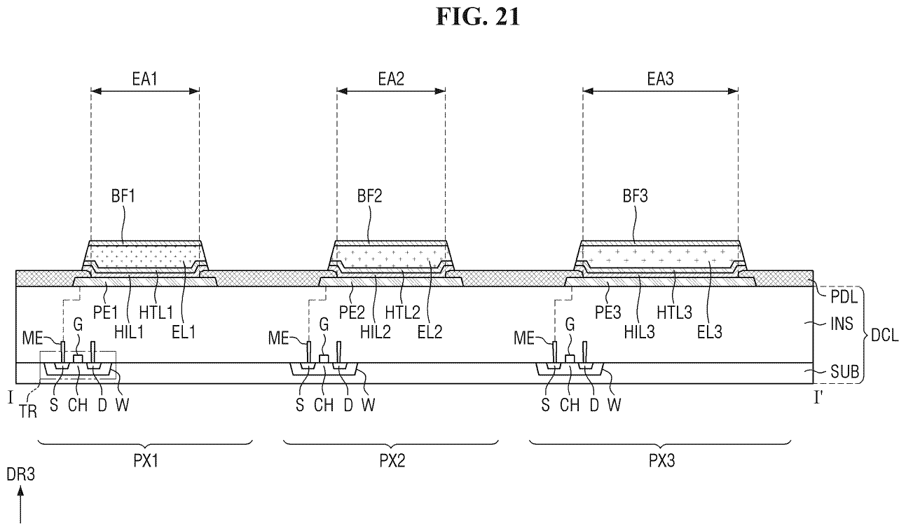

Afterwards, as shown in FIG. 21, the first sacrificial layer SAL1, the second sacrificial layer SAL2, and the third sacrificial layer SAL3 may be removed. For example, the first sacrificial layer SAL1, the second sacrificial layer SAL2, and the third sacrificial layer SAL3 may be removed by wet etching. At this time, an etchant used for the wet etching may have a sufficiently large etch rate so that only the first sacrificial layer SAL1, the second sacrificial layer SAL2, and the third sacrificial layer SAL3 may be selectively removed by the etchant.

Then, the substrate SUB from which the first to third sacrificial layers SAL1 to SAL3 are removed may be cleaned. A cleaning solution used for the cleaning process may include deionized water.

The cleaned substrate SUB may be disposed inside a vacuum chamber. In a vacuum state, the substrate SUB may be baked at a high temperature. For example, the substrate SUB may be baked at a temperature of about 90° C. Any moisture remaining in the substrate SUB may be removed by the baking process.

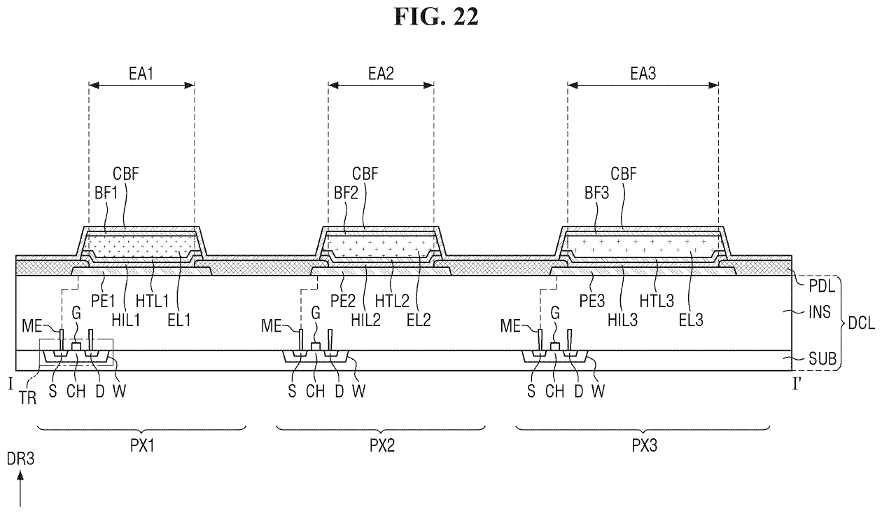

As shown in FIG. 22, the common buffer layer CBF may be disposed on the first buffer layer BF1, the second buffer layer BF2, the third buffer layer BF3, and the pixel defining layer PDL in the vacuum chamber. For example, the common buffer layer CBF may be formed on the first buffer layer BF1, the second buffer layer BF2, the third buffer layer BF3, and the pixel defining layer PDL while in a vacuum state.

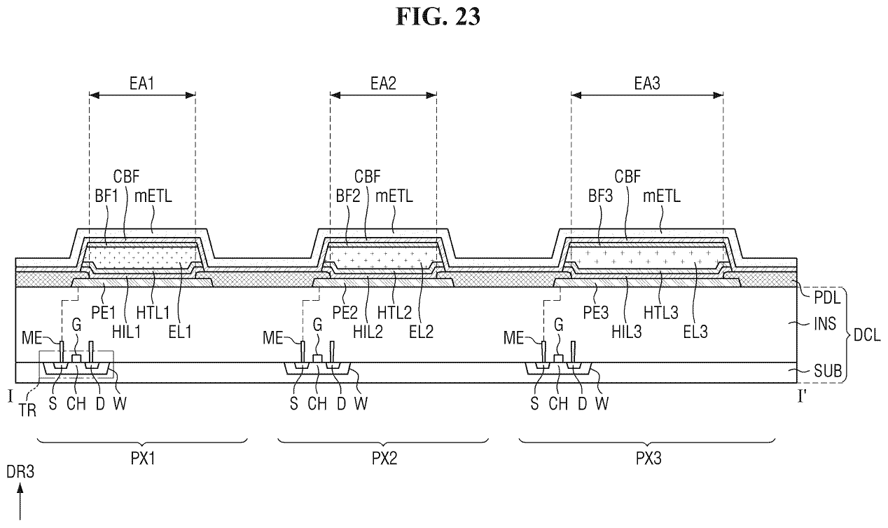

Then, as shown in FIG. 23, the electron transport layer mETL may be disposed on the common buffer layer CBF in the vacuum chamber. For example, the electron transport layer mETL may be formed on the common buffer layer CBF while in a vacuum state.

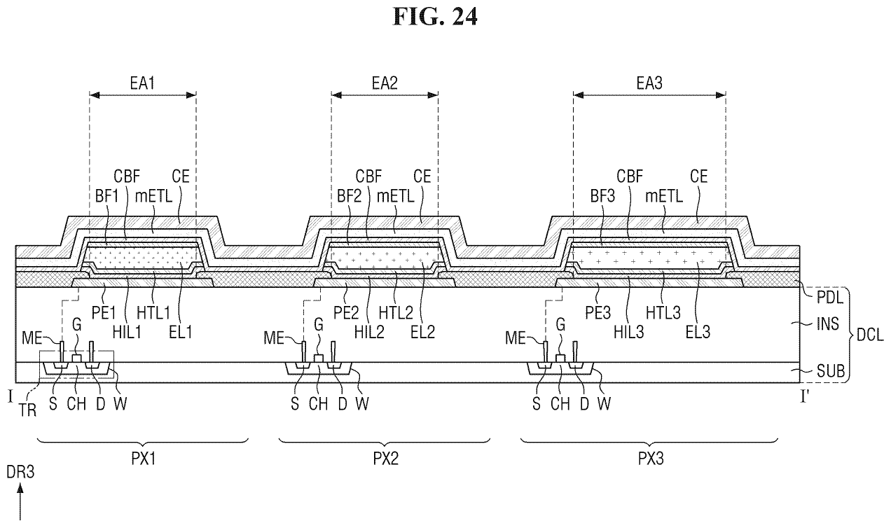

Afterwards, as shown in FIG. 24, the common electrode CE may be disposed on the electron transport layer mETL in the vacuum chamber. For example, the common electrode CE may be formed on the electron transport layer mETL while in a vacuum state.

Next, as shown in FIG. 6, the encapsulation layer ENC may be disposed on the common electrode CE in the vacuum chamber. For example, the encapsulation layer ENC may be formed on the common electrode CE while in a vacuum state.

In the method for fabricating the display device according to one or more embodiments, because the light emitting layer and the like may be fabricated by the photolithography process without using the existing fine metal mask, a high-resolution product having a narrower interval between adjacent pixels may be fabricated. In addition, because the light emitting layer according to one or more embodiments may be formed by a photo pattern process, the light emitting layer may have a clear side without a tail defect, and thus, a defect that may be caused by a lateral leakage current may be suppressed.

As used herein, the tail defect may refer to a portion of the material of the light emitting layer that is formed up to a portion that overlaps with the non-light emission area, in addition to the light emission area, by an interval between the fine metal mask and the substrate when the light emitting layer is formed by a deposition process using the fine metal mask. In other words, the tail defect formed in the portion overlapped with the non-light emission area may be expressed as a mask shadowing defect. The tail defect and the mask shadowing defect may result in the lateral leakage current as described above.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate;
a first electrode on the substrate;
a light emitting layer on the first electrode;
a pixel defining layer on the light emitting layer; and
a second electrode on the light emitting layer,
wherein first and second opposite sides of the light emitting layer are located on the pixel defining layer, and have straight line shapes that are inclined at an angle with respect to an upper surface of the pixel defining layer.

2. The display device of claim 1, wherein an angle between the upper surface of the pixel defining layer and the first side of the light emitting layer is greater than 60° and smaller than or equal to 90°, and
wherein an angle between the upper surface of the pixel defining layer and the second side of the light emitting layer is greater than 60° and smaller than or equal to 90°.

3. The display device of claim 1, wherein a distance between the first side of the light emitting layer and the second side of the light emitting layer gradually decreases in a direction away from the pixel defining layer.

4. The display device of claim 1, further comprising a first functional layer between the first electrode and the light emitting layer.

5. The display device of claim 4, wherein first and second opposite sides of the first functional layer are located on the pixel defining layer, and have straight line shapes inclined at an angle with respect to the upper surface of the pixel defining layer.

6. The display device of claim 5, wherein an angle between the upper surface of the pixel defining layer and the first side of the first functional layer is greater than 60° and smaller than or equal to 90°, and
wherein an angle between the upper surface of the pixel defining layer and the second side of the first functional layer is greater than 60° and smaller than or equal to 90°.

7. The display device of claim 5, wherein a distance between the first side of the first functional layer and the second side of the first functional layer gradually decreases in a direction away from the pixel defining layer.

8. The display device of claim 4, wherein the first functional layer comprises:
a hole injection layer on the first electrode; and
a hole transport layer on the hole injection layer.

9. The display device of claim 1, further comprising a second functional layer between the light emitting layer and the second electrode.

10. The display device of claim 9, wherein first and second opposite sides of the second functional layer are located on the pixel defining layer, and
wherein the first and second sides of the second functional layer have straight line shapes inclined at an angle with respect to the upper surface of the pixel defining layer.

11. The display device of claim 10, wherein an angle between the upper surface of the pixel defining layer and the first side of the second functional layer is greater than 60° and smaller than or equal to 90°, and
wherein an angle between the upper surface of the pixel defining layer and the second side of the second functional layer is greater than 60° and smaller than or equal to 90°.

12. The display device of claim 10, wherein a distance between the first side of the second functional layer and the second side of the second functional layer gradually decreases in a direction away from the pixel defining layer.

13. The display device of claim 9, wherein the second functional layer comprises a buffer layer on the light emitting layer.

14. The display device of claim 9, further comprising a common buffer layer between the second functional layer and the second electrode.

15. The display device of claim 14, further comprising a first functional layer between the first electrode and the light emitting layer,
wherein the common buffer layer is located on the first and second sides of the light emitting layer, first and second sides of the first functional layer, and first and second sides of the second functional layer.

16. The display device of claim 14, further comprising an electron transport layer between the common buffer layer and the second electrode.

17. The display device of claim 16, wherein, in a plan view, the electron transport layer is located on the common buffer layer to surround the light emitting layer.

18. The display device of claim 1, further comprising an encapsulation layer on the second electrode.

19. The display device of claim 1, wherein the pixel defining layer comprises an inorganic layer.

20. A method for fabricating a display device, the method comprising:
disposing a first electrode on a substrate;
disposing a pixel defining layer on the first electrode;
disposing a first functional layer, a light emitting layer, a second functional layer, and a sacrificial layer on an entire surface of the substrate including the pixel defining layer;
disposing a photoresist pattern on the sacrificial layer to overlap with the first electrode;
etching the first functional layer, the light emitting layer, the second functional layer, and the sacrificial layer by using the photoresist pattern as a mask so that the first functional layer, the light emitting layer, the second functional layer, and the sacrificial layer are disposed between the first electrode and the photoresist pattern;
removing the photoresist pattern; and
removing the etched sacrificial layer.

21. The method of claim 20, further comprising cleaning the substrate including the etched first functional layer, the etched light emitting layer, and the etched second functional layer.

22. The method of claim 21, further comprising:
disposing the cleaned substrate in a vacuum chamber; and
baking the substrate in the vacuum chamber.

23. The method of claim 22, further comprising disposing a common buffer layer on the second functional layer of the baked substrate in the vacuum chamber.

24. The method of claim 23, further comprising disposing an electron transport layer on the common buffer layer in the vacuum chamber.

25. The method of claim 24, further comprising disposing a second electrode on the electron transport layer in the vacuum chamber.

26. The method of claim 20, wherein, in the etching of the first functional layer, the light emitting layer, the second functional layer, and the sacrificial layer by using the photoresist pattern as a mask, the first functional layer, the light emitting layer, the second functional layer, and the sacrificial layer are etched by dry etching.

27. The method of claim 20, wherein, in the removing of the etched sacrificial layer, the etched sacrificial layer is removed by an etchant.

28. The method of claim 20, wherein the sacrificial layer comprises at least one of aluminum or silver.
